(19) United States
(12) Patent Application Publication
(10) Pub. No.: US 2008/0157142 A1
(43) Pub. Date: Jul. 3, 2008

(54) METHOD FOR MANUFACTURING OF CMOS IMAGE SENSOR

(75) Inventor: Jeong Su Park, Incheon (KR)

Correspondence Address: WORKMAN NYDEGGER, 60 EAST SOUTH TEMPLE, 1000 EAGLE GATE TOWER, SALT LAKE CITY, UT, 84111, US

(73) Assignee: DONGBU HITEK CO., LTD., Seoul (KR)

(21) Appl. No.: 11/926,029

(22) Filed: Oct. 28, 2007

(30) Foreign Application Priority Data
Dec. 29, 2006 (KR) 10-2006-0137304

(51) Int. Cl. H01L 31/113; H01L 31/18

(52) U.S. Cl. 257/292; 438/69; 257/E31.073

(57) ABSTRACT

The present invention relates to a method for manufacturing a CMOS image sensor. The method comprises forming a photodiode and a transistor on a semiconductor substrate which is divided into a pixel region and a peripheral region, forming a plurality of oxide films and metal wiring on the semiconductor substrate, depositing a silicon oxynitride (SiON) layer on the oxide film, performing an array etch in the pixel region in order to reduce the optical length of the pixel region, depositing a silicon nitride (SiN) layer over the etched pixel region and silicon oxynitride layer, and forming a micro lens on the silicon nitride layer. Advantageously, the method prevents the generation of circular defects in the peripheral region while maintaining the refractive index in the pixel region.

### CROSS-REFERENCES AND RELATED APPLICATIONS

This application claims the benefit of the Korean Patent Application No. 10-2006-0137304, filed on Dec. 29, 2006, which is hereby incorporated by reference in its entirety.

### BACKGROUND OF THE INVENTION

1. Field of the Invention

The present invention relates to a method for manufacturing a CMOS image sensor. More particularly, the present invention relates to a method for manufacturing a CMOS image sensor which is capable of preventing circular defects from being generated in the peripheral region of the CMOS image sensor.

2. Discussion of the Related Art

Generally, an image sensor is used in a semiconductor device to convert an optical image into an electrical signal. A charge coupled device (CCD) is a device having individual metal-oxide-silicon capacitors for storing electrical charge, which are located so as to be very close to each other.

In a complementary metal-oxide-semiconductor, or “CMOS” circuit, an image sensor is a device that has MOS transistors which correspond to the number of pixels. Using CMOS technology, the control circuit and a signal processing circuit detecting a series of outputs from the image sensor and its transistors.

FIGS. 1A to 1C are process cross-sectional views showing a method for manufacturing a CMOS image sensor typically used in the related art. As shown in FIG. 1A, after forming a photodiode 110 capable of detecting RGB signals on the lower of the semiconductor substrate 100 in a continuous epitaxial layer and an ion implanting process, a transistor (not shown) is formed in order to transfer signals, and an oxide film 120 and a plurality of metal wiring 130 are formed.

As shown in FIG. 1B, since the pixel region has a three-step metal wiring structure and the peripheral region has a five-step metal wiring structure, an array etch is performed to remove a portion of the oxide film above the pixel region, in order reduce the optical length of the pixel region. Next, as shown in FIG. 1C, a passivation nitride film 140 is deposited over the semiconductor substrate 100 and oxide film 120. Then a micro lens 150 is formed on the passivation nitride film 140 in the pixel region.

However, one difficulty that is often found in the method for manufacturing the CMOS image sensor known in the art is that circular defects 200, such as the defects shown in FIG. 2, may be generated in the peripheral region of the five-step metal wiring structure when silicon nitride SiN is used as the passivation nitride film 140. Herein, the circular defect 200 is a circular defect which results from the propagation of a crack generated at an edge of the metal wiring 130 to the outside surface that occurs immediately after performing a thermal treatment on the device since the metal wiring 130, the oxide film 120, and the silicon nitride each have different thermal expansion properties.

Meanwhile, the change in stress applied to a silicon nitride film after the thermal treatment process is 90 MPa or more, while only about 40 MPa in a silicon oxynitride (SiON) layer. Thus, the silicon oxynitride can be used as the passivation nitride film 140 in order to reduce the internal stresses within the image sensor.

One difficulty in using silicon oxynitride, however, is that the properties of the CMOS sensor, such as array etch depth and thickness of the micro lens 150 are vary according to the refractive index of the film, so using silicon oxynitride instead of the silicon nitride may be difficult.

### BRIEF SUMMARY OF THE INVENTION

The present invention proposes to solve the aforementioned problems. It is an object of the present invention to provide a method for manufacturing a CMOS image sensor which prevents circular defects from being generated in a peripheral region of the CMOS image sensor.

In order to accomplish this object, one aspect of the invention is a method for manufacturing a CMOS image sensor comprising forming a photodiode and a transistor on a semiconductor substrate, wherein the semiconductor substrate is divided into a pixel region and a peripheral region, forming an oxide film and a metal wiring pattern on the semiconductor substrate, depositing a silicon oxynitride (SiON) layer on the oxide film, performing an array etch on the oxide film and silicon oxynitride layer in order to reduce an optical length in the pixel region, depositing a silicon nitride (SiN) layer over the semiconductor substrate, oxide film, and silicon oxynitride layer, and forming a micro lens on the silicon nitride layer.

### BRIEF DESCRIPTION OF THE DRAWINGS

The accompanying drawings are included to provide a further understanding of the invention and are incorporated in and constitute a part of this application. The drawings illustrate embodiment(s) of the invention and together with the description serve to explain the principle of the invention. In the drawings:

FIGS. 1A to 1C illustrate a method for manufacturing a CMOS image sensor known in the related art;

FIG. 2 is a view showing an exemplary circular defect generated in a peripheral region of the CMOS image sensor using the manufacturing method described in FIGS. 1A to 1C; and

FIGS. 3A to 3D illustrate a method of manufacturing a CMOS image sensor according to one embodiment of the present invention.

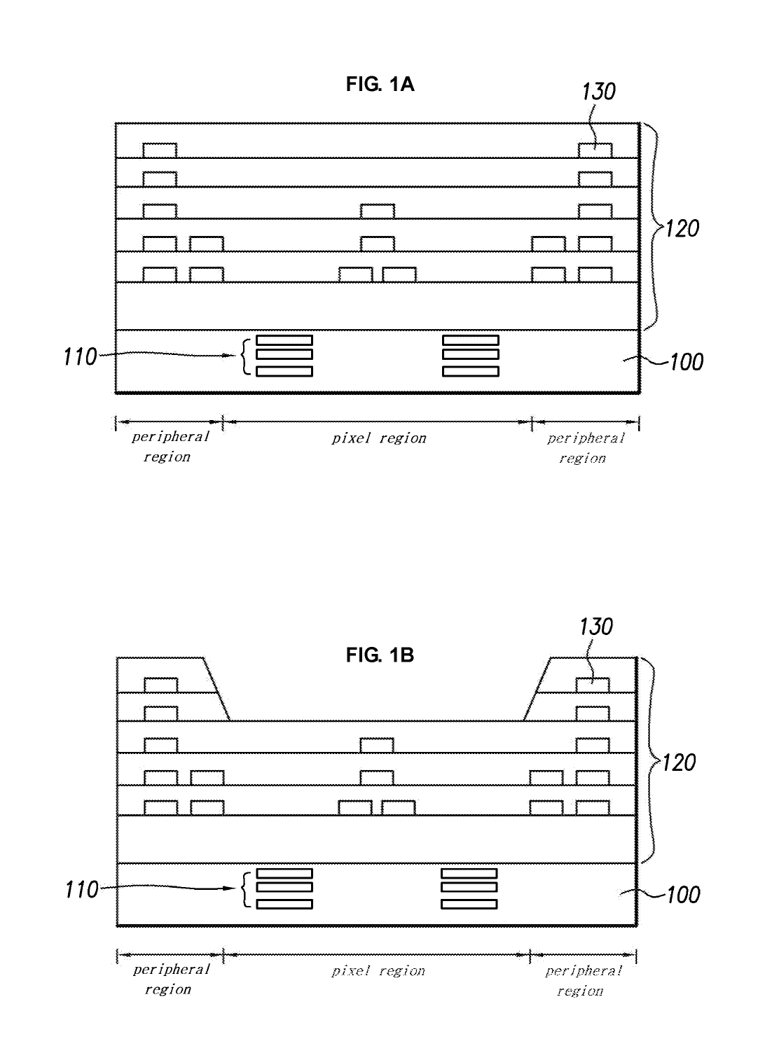

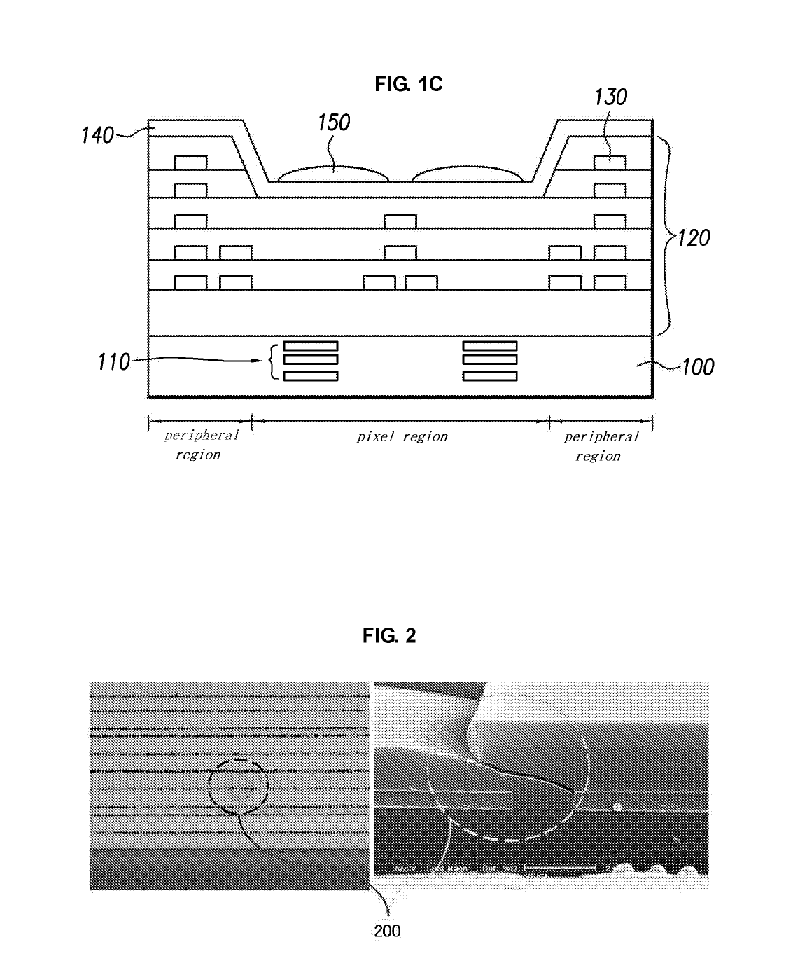

### DETAILED DESCRIPTION OF THE INVENTION

Hereinafter, the preferred embodiment of the present invention will be described in detail with reference to the accompanying drawings. Detailed descriptions of well-known techniques will be omitted so as not to obscure the novel features of the invention with unnecessary detail.

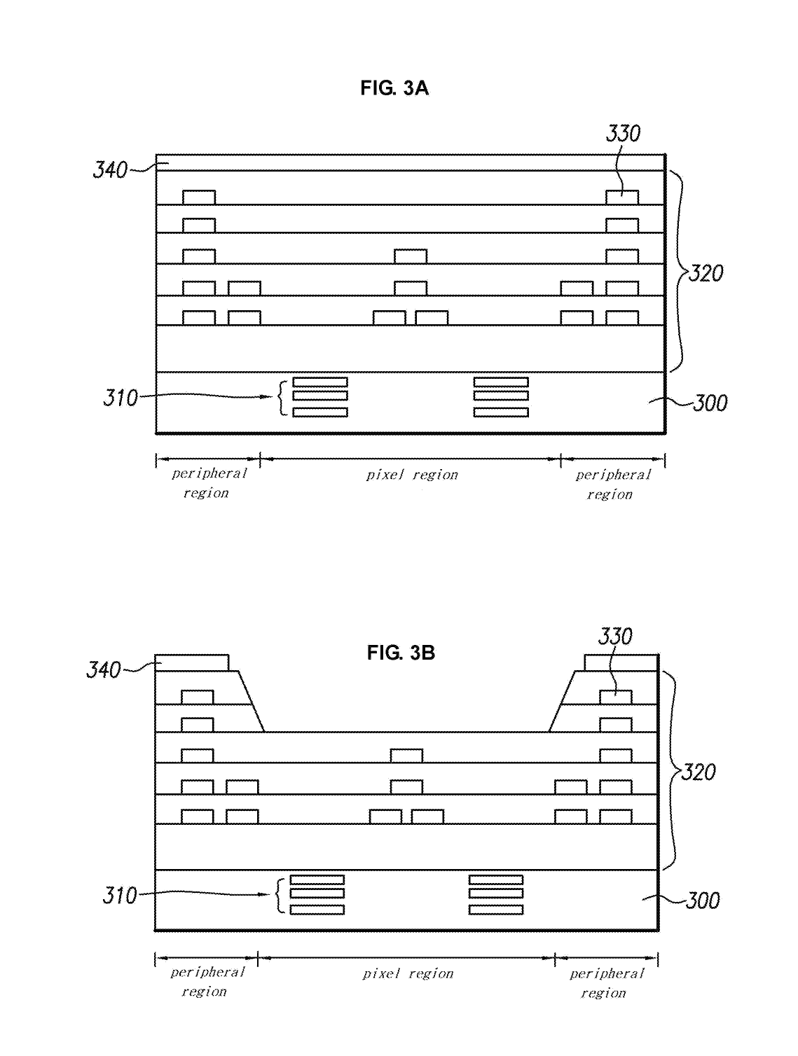

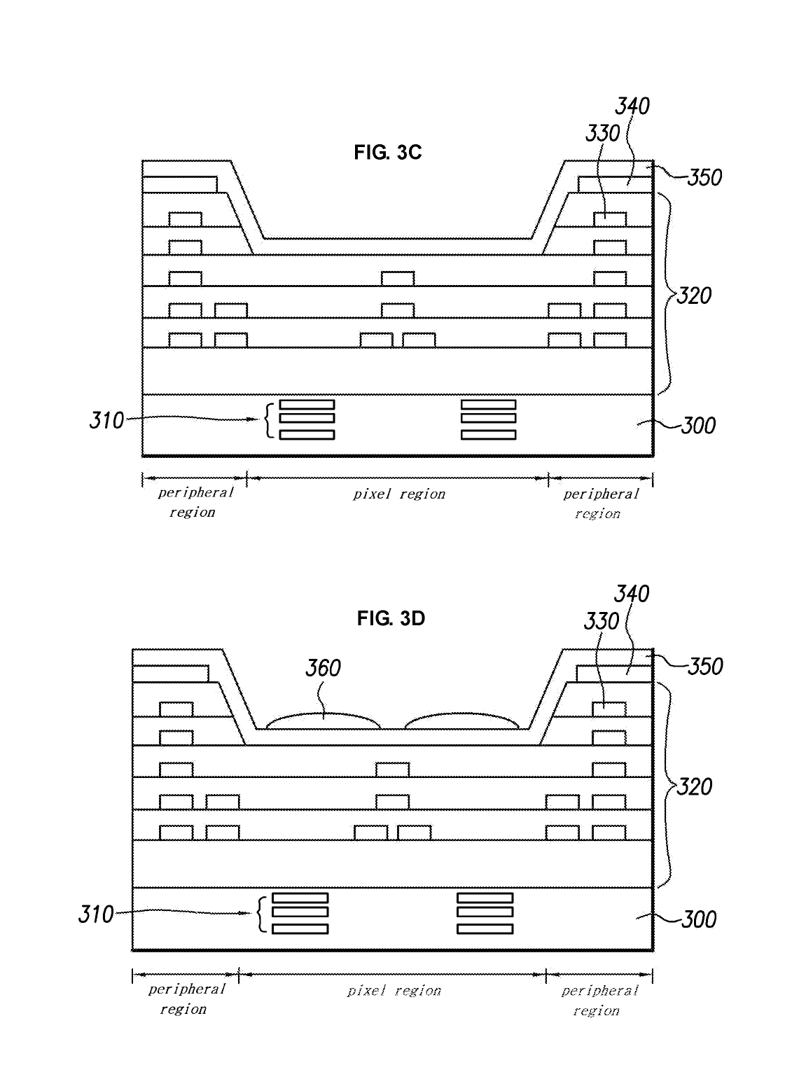

FIGS. 3A to 3D illustrate a method of manufacturing a CMOS image sensor according to one embodiment of the present invention. As shown in FIG. 3A, a photodiode 310 capable of detecting RGB signals and a transistor (not shown) capable of transferring signals are both formed on a semiconductor substrate 300 on which an epitaxial layer (not shown) is grown. As a result, an oxide film 320 and a metal wiring 330 are formed on the semiconductor substrate 300 which is divided into a pixel region and a peripheral region. In this configuration, the pixel region has a three-step metal wiring structure while the peripheral region has a five-step metal wiring structure.

As shown in FIG. 3B, the silicon oxynitride (SiON) layer 340 is deposited on the oxide film 320 at a thickness of 3000 Å using a chemical vapor deposition or “CVD” process.

Next, an array etch is performed on the oxynitride layer and oxide film in the pixel region in order to reduce the optical length of the pixel region. In particular, the array etch is performed a layer of the oxide film 320 of the pixel region is exposed. As a result, the silicon oxynitride layer 340 remains in the peripheral region while being removed in the pixel region, exposing the oxide film 320.

Next, as shown in FIG. 3C, a silicon nitride (SiN) layer 350 is deposited over the surface, including the silicon oxynitride layer 340 and oxide film 320. Accordingly, there is a silicon nitride layer 350 covering the top of the pixel region, while there are both silicon oxynitride and silicon nitride layers 340 and 350 on the top of the pixel region.

Because the structure of the pixel region of the invention is the same as the structure of the pixel region known in the art, there is no effect in image characteristics. In contrast, however, in the peripheral region of the present invention the silicon oxynitride layer 340 is below the silicon nitride layer 350, meaning the change in the stress generated due to a subsequent thermal process smaller than in the peripheral region of the current art. Thus, the present invention is capable of preventing circular defects in the peripheral region.

Next, as shown in FIG. 3D, a photoresist film (not shown) is coated on the silicon nitride 350 and a micro lens pattern (not shown) is formed by selectively exposing and developing the photoresist film during an etching process. Then, a micro lens 360 with a curved surface is formed by performing a thermal treatment process.

Although the preferred embodiments of the present invention have been described above, the present invention can be implemented in a modified form by those skilled in the art without departing from the essential properties of the present invention.

Therefore, the embodiment of the present invention described herein should be considered as illustrative only, rather than as limiting. Thus, the scope of the present invention is shown in the claims, rather than the above description, and all differences present within equivalents should be construed as included in the present invention.

In the present invention described above, a CMOS image sensor may be formed wherein the passivation nitride film is formed of the silicon oxynitride and the silicon nitride so that the circular defects can be prevented from forming in the peripheral region of the CMOS image sensor while minimizing the change in refractive index in the pixel region. Thus, one aspect of the present invention is improved image quality.

What is claimed is:

1. A method for manufacturing a CMOS image sensor comprising:
forming a photodiode and a transistor on a semiconductor substrate divided into a pixel region and a peripheral region;
forming a plurality of oxide films and metal wiring on the semiconductor substrate;
depositing silicon oxynitride (SiON) layer on the oxide film;
performing an array etch on silicon oxynitride layer in order to reduce an optical length of the pixel region;
depositing a silicon nitride (SiN) layer over pixel region and silicon oxynitride layer of the peripheral region; and
forming a micro lens on the silicon nitride layer.

2. The method according to claim 1, wherein the photodiode and transistor are formed on an epitaxial layer grown on the substrate.

3. The method according to claim 1, wherein the metal wiring is formed into a three-step metal wiring structure in the pixel region and a five-step metal wiring structure in the peripheral region.

4. The method according to claim 1, wherein the silicon oxynitride (SiON) is deposited on the oxide film at a thickness of 3000 Å using a chemical vapor deposition process.

5. The method according to claim 1, wherein the silicon oxynitride layer is removed in the pixel region during the array etch while remaining in the peripheral region.

6. The method according to claim 1, wherein the array etch is performed until the oxide film of the pixel region is exposed.

7. The method according to claim 1, wherein the silicon nitride (SiN) layer is deposited after performing the array etch so that the silicon oxynitride is formed over the pixel region and the silicon oxynitride and the silicon nitride are both formed over the peripheral region.

8. A CMOS image sensor comprising:
a semiconductor substrate divided into a pixel region and a peripheral region;
a photodiode formed in the semiconductor substrate;
a transistor formed in the semiconductor substrate;
a plurality of oxide films and metal wiring formed on the semiconductor substrate;
a silicon oxynitride (SiON) layer formed on the oxide film in the peripheral region;
a silicon nitride (SiN) layer over pixel region and silicon oxynitride layer of the peripheral region; and
a micro lens formed on the silicon nitride layer.

9. The sensor of claim 8, further comprising a epitaxal layer in the substrate, wherein the photodiode and transistor are formed on the epitaxial layer.

10. The sensor of claim 8, wherein the metal wiring has a three-step metal wiring structure in the pixel region and a five-step metal wiring structure in the peripheral region.

11. The sensor of claim 8, wherein the silicon oxynitride (SiON) has a thickness of 3000 Å and is formed in a chemical vapor deposition process.

12. The sensor of claim 8, wherein the number of oxide films in the pixel region is less than the number of oxide films in the peripheral region so that the optical length of the pixel region is smaller than the optical length in the peripheral region.
